(19) United States
(12) Patent Application Publication
(10) Pub. No.: US 2019/0044258 A1
(43) Pub. Date: Feb. 7, 2019

(54) CABLE CONNECTOR BLOCK ASSEMBLIES FOR BASE STATION ANTENNAS

(71) Applicant: CommScope Technologies LLC, Hickory, NC (US)

(72) Inventors: Paul D. Everest, Flower Mound, TX (US); Amit Kaistha, Coppell, TX (US); Troy I. Vanderhoof, Prosper, TX (US); Xiangyang Ai, Plano, TX (US)

(21) Appl. No.: 16/052,844

(22) Filed: Aug. 2, 2018

Related U.S. Application Data
(60) Provisional application No. 62/541,843, filed on Aug. 7, 2017.

(51) Int. Cl. H01R 12/51; H01R 4/02; H05K 1/18; H05K 1/14; H01Q 1/38; H01Q 1/24; H01Q 15/14

(52) U.S. Cl. CPC H01R 12/515; H01R 4/027; H05K 1/184; H05K 1/14; H01Q 1/38; H05K 2201/048; H01Q 15/14; H05K 2201/10393; H05K 2201/10356; H05K 2201/10098; H05K 2201/09063; H01Q 1/246

(57) ABSTRACT

Cable connector block assemblies for base station antennas are provided herein. A cable connector block assembly includes a block including a cable retention clip, a first metal piece, and a second metal piece. In some embodiments, the first and second metal pieces are in first and second recesses, respectively, of the block. Moreover, in some embodiments, the cable retention clip, the first metal piece, and the second metal piece are configured to receive different first, second, and third portions, respectively, of a cable.

### CROSS-REFERENCE TO RELATED APPLICATION

The present application claims priority under 35 U.S.C. § 119 to U.S. Provisional Patent Application Ser. No. 62/541,843, filed Aug. 7, 2017, the entire content of which is incorporated herein by reference as if set forth in its entirety.

### FIELD

The present disclosure relates to communication systems and, in particular, to cable connector assemblies for base station antennas.

### BACKGROUND

Base station antennas for wireless communication systems are used to transmit Radio Frequency (RF) signals to, and receive RF signals from, fixed and mobile users of a cellular communications service. Base station antennas often include different components that are connected to each other via cables. A cable connector assembly may support the cables, and ends of the cables may be directly connected to the components via solder junctions.

For example, FIG. 1 is a perspective view of a prior art cable connector assembly. The assembly includes a plastic retention structure 120 with cable clips 120C that restrict movement of antenna RF cables 130. The antenna RF cables 130 are soldered directly to a Printed Circuit Board (PCB) 110. For example, solder regions 110S may surround center conductors 130C of the cables 130. A gap 115 is provided between the PCB 110 and the plastic retention structure 120. The gap 115 could be, for example, a cutout in a metal frame of a phase shifter assembly of a base station antenna. Unfortunately, the center conductors and ground sleeves of the cables 130 are prone to bending during assembly and may stress solder joints such as the solder region 1105, thus impairing reliability.

Stressed solder joints may result in Passive Intermodulation (PIM). PIM is a form of electrical interference/signal transmission degradation that may occur at interconnections, such as solder joints, where a non-linearity is introduced into the connection, either as initially installed or due to electro-mechanical shift over time. Interconnections may shift due to mechanical stress, vibration, thermal cycling, and/or material degradation. PIM can be an important interconnection quality characteristic, as PIM generated by a single low quality interconnection may degrade the electrical performance of an entire RF system. The reduction of PIM via connector design is thus typically desirable.

### SUMMARY

A cable connector support structure, according to some embodiments herein, may include a connector block. The connector block may include a plurality of cable retention clips on a first end of the connector block. The connector block may include a first plurality of recesses adjacent the plurality of cable retention clips. Moreover, the connector block may include a second plurality of recesses on a second end of the connector block that is opposite the first end. The cable connector support structure may include metal in the first plurality of recesses. The cable connector support structure may include a plurality of metal pieces in the second plurality of recesses, respectively. The plurality of metal pieces may include respective recessed portions that are shallower and narrower than respective recessed portions of the metal in the first plurality of recesses.

In some embodiments, the cable connector support structure may include a base station antenna Printed Circuit Board (PCB) that includes openings through which the metal and the plurality of metal pieces protrude. Moreover, the metal may include a first plurality of metal pieces in the first plurality of recesses, respectively, and the plurality of metal pieces in the second plurality of recesses may include a second plurality of metal pieces. Alternatively, the metal may include a single, continuous metal piece that is in each of the first plurality of recesses.

An antenna cable connector support structure, according to some embodiments herein, may include a connector block. The connector block may include a pair of antenna cable retention clip sidewalls on a first portion of the connector block. The connector block may include a first recess on a second portion of the connector block. Moreover, the connector block may include a second recess between the first recess and the pair of antenna cable retention clip sidewalls. The antenna cable connector support structure may include first and second metal pieces in the first and second recesses, respectively.

In some embodiments, the first and second portions of the connector block may include first and second ends, respectively, of the connector block. Moreover, the antenna cable connector support structure may include a base station antenna Printed Circuit Board (PCB) including first and second openings through which the first and second metal pieces, respectively, protrude.

According to some embodiments, the first and second recesses may be aligned with respect to the pair of antenna cable retention clip sidewalls. In some embodiments, the antenna cable connector support structure may include a third recess that extends between the first and second recesses. The third recess may be shallower than the first recess, and the first recess may be shallower than the second recess. The first metal piece may include a recessed portion that is shallower and narrower than a recessed portion of the second metal piece, and the third recess may be equally shallow and narrow as the recessed portion of the first metal piece. Accordingly, a portion of the first metal piece may be coplanar with a portion of the third recess.

In some embodiments, the pair of antenna cable retention clip sidewalls may protrude from the connector block in a first direction, and the first and second metal pieces may include respective protruding portions that protrude from the connector block in a second direction that is opposite the first direction. Additionally or alternatively, the antenna cable connector support structure may include a base station antenna feedboard assembly having a Printed Circuit Board (PCB) with first and second openings through which the first and second metal pieces, respectively, protrude.

A cable connector block assembly, according to some embodiments herein, may include a plastic block. The plastic block may include a cable retention clip, a first metal piece, and a second metal piece that are configured to receive different first, second, and third portions, respectively, of a cable. Moreover, the cable connector block assembly may include a Printed Circuit Board (PCB) that includes first and second openings through which the first and second metal pieces, respectively, protrude.

In some embodiments, the cable connector block assembly may include an adhesive material connecting the plastic block and the PCB. Additionally or alternatively, the cable retention clip may protrude in a first direction, the plastic block may include a protruding portion that protrudes in a second direction that is opposite the first direction, and the PCB may include a third opening that is configured to receive the protruding portion of the plastic block.

According to some embodiments, the first metal piece may include a recessed portion that is shallower and narrower than a recessed portion of the second metal piece. Additionally or alternatively, the cable retention clip, the first metal piece, and the second metal piece of the plastic block may be configured to receive different first, second, and third portions, respectively, of a base station antenna cable. For example, PCB may be a phase shifter assembly PCB of a base station antenna.

In some embodiments, PCB may be a PCB of a feedboard assembly of a base station antenna. Moreover, the cable connector block assembly may include an antenna reflector on the feedboard assembly. The antenna reflector may include an opening through which the cable retention clip of the plastic block protrudes. Additionally or alternatively, the PCB of the feedboard assembly may include first and second openings through which first and second feed stalk Printed Circuit Boards (PCBs) protrude, and the first and second PCBs may be connected to a radiating element of the base station antenna.

According to some embodiments, the cable retention clip may be a first cable retention clip that is configured to receive a first cable that extends in a first direction. Moreover, the plastic block may include a second cable retention clip that is configured to receive a second cable that extends in a second direction that intersects the first direction at an oblique angle.

### BRIEF DESCRIPTION OF THE DRAWINGS

FIG. 1 is a perspective view of a prior art cable connector assembly.

FIG. 2A is a perspective view of a cable connector block assembly that may be used with base station antennas according to embodiments of present inventive concepts.

FIG. 2B is an exploded view of the cable connector block assembly of FIG. 2A.

FIG. 2C is a plan view of the cable connector block assembly of FIG. 2A.

FIG. 2D is a cross-sectional view taken along the line A-A′ of FIG. 2C.

FIG. 2E is a perspective view of a cable connector block assembly that may be used with base station antennas according to embodiments of present inventive concepts.

FIG. 2F is an exploded view of the cable connector block assembly of FIG. 2E.

FIG. 3A is a perspective view of a cable connector block assembly that may be used with base station antennas according to embodiments of present inventive concepts.

FIG. 3B is an exploded view of the cable connector block assembly of FIG. 3A.

FIG. 3C is a perspective view of the cable connector block assembly of FIG. 3A attached to a feedboard of a base station antenna according to embodiments of present inventive concepts.

FIG. 3D is an exploded view of the cable connector block assembly and feedboard of FIG. 3C.

FIG. 3E is a perspective view of an antenna reflector on the feedboard of FIG. 3C according to embodiments of present inventive concepts.

FIG. 3F is an exploded view of the antenna reflector and feedboard of FIG. 3E.

### DETAILED DESCRIPTION

Pursuant to embodiments of present inventive concepts, cable connector block assemblies are provided for base station antennas. Each cable connector block assembly may include a connector block that is mounted to a Printed Circuit Board (PCB) before soldering metal of the cable connector block assembly to the PCB. This may help to reduce stress at solder joints, and thus may increase reliability and reduce Passive Intermodulation (PIM).

Each cable connector block assembly may be used with antenna Radio Frequency (RF) cables. For example a cable connector block assembly may be used with cables that connect to a feedboard assembly of a base station antenna or to a phase shifter assembly of a base station antenna. Accordingly, the PCB to which the connector block is mounted may be (i) a PCB of a phase shifter assembly or (ii) a PCB of a feedboard assembly. Alternatively, in some embodiments, the cable connector block assembly may be used with a filter of a base station antenna.

Because all of the cable retention clips and retention features may be located in one part/block, the tolerances of the cables to the retention features may be significantly tighter than conventional systems in which parts are separate. In particular, by using cable connector block assemblies according to embodiments herein, the location of features can be well-defined and process variation can be reduced. Moreover, the cable connector block assemblies according to embodiments herein may inhibit bending of the cables and may facilitate strong solder joints.

A cable connector block assembly pursuant to embodiments herein may thus simplify antenna RF cable connections by consolidating support for multiple portions of a cable in a single block, and may improve the solderability of the antenna RF cable connections by using rounded metal recess channels in the block. Specifically, the cable connector block assembly may help restrict undesired movement of the antenna RF cables, and may strengthen electrical connections with the antenna RF cables, thereby improving performance of the associated base station antenna.

Example embodiments of present inventive concepts will be described in greater detail with reference to the attached figures.

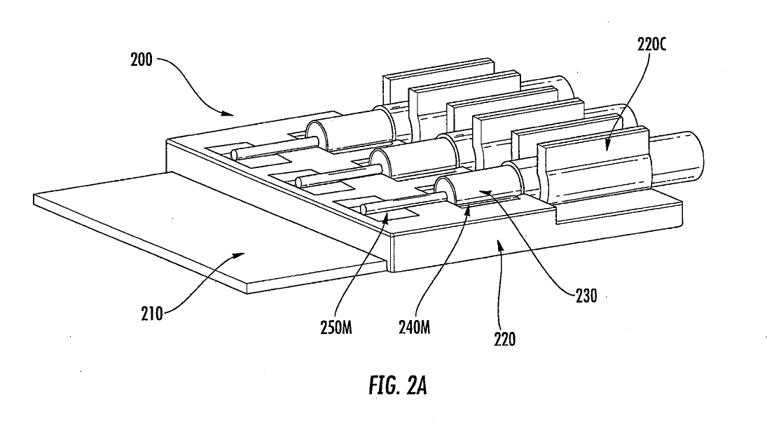

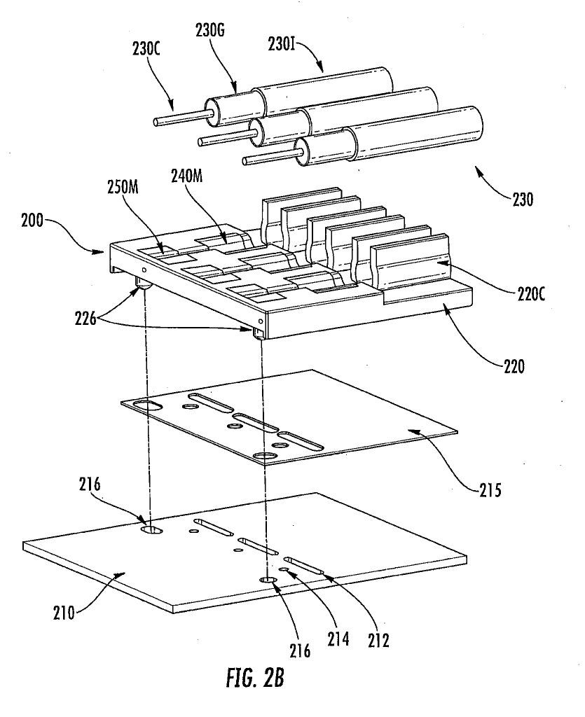

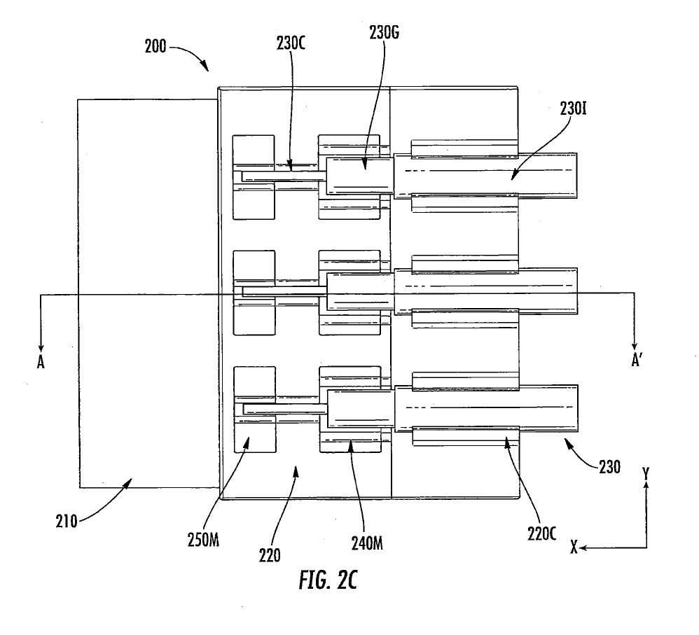

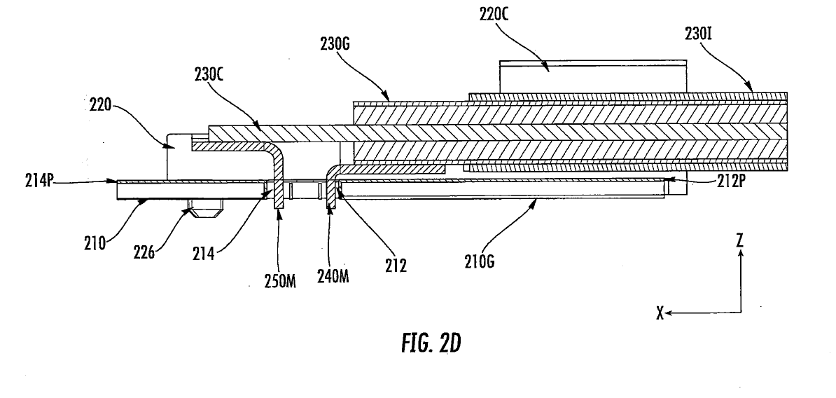

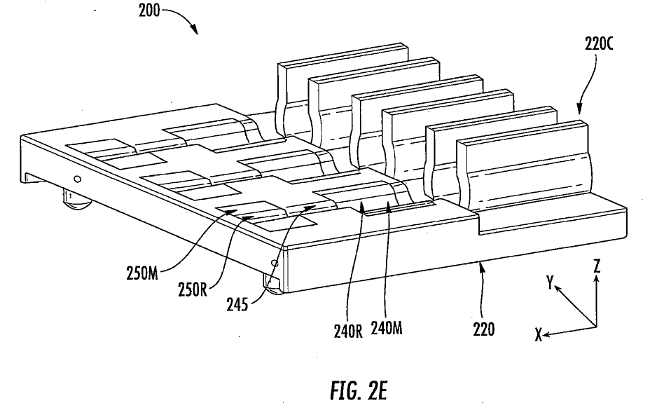

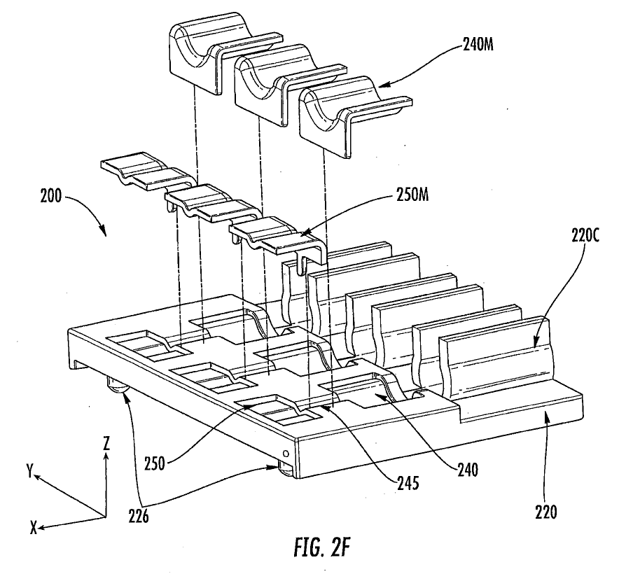

FIG. 2A is a perspective view of a cable connector block assembly 200 that may be used with base station antennas according to embodiments of present inventive concepts. The cable connector block assembly 200 includes a connector block 220 having a plurality of cable retention clips 220C. The plurality of clips 220C is configured to receive and retain a plurality of antenna RF cables 230, respectively. Specifically, the clips 220C hold the cables 230 in place during a soldering process and provide strain relief when a tower supporting a base station antenna that includes the cable connector block assembly 200 is subject to wind or other vibrations.

The clips 220C may be on a first end of the connector block 220. The cable connector block assembly 200 also includes metals 240M, 250M in recessed portions of the connector block 220. The metals 240M may be adjacent the clips 220C, and the metals 250M may be on a second end of the connector block 220 that is opposite the first end. Moreover, the connector block 220 may be mounted on a Printed Circuit Board (PCB) 210. The combination of the connector block 220 and its associated metals 240M, 250M and/or PCB 210 may be referred to as the “cable connector block assembly.”

FIG. 2B is an exploded view of the cable connector block assembly 200 of FIG. 2A. FIG. 2B illustrates that an adhesive layer 215 may optionally be between the connector block 220 and the PCB 210. The shape of, and openings in, the adhesive layer 215 may conform to the PCB 210. Additionally or alternatively, one or more protruding portions 226 of the connector block 220 may extend through respective openings 216 in the PCB 210. Accordingly, each opening 216 is configured to receive a respective protruding portion 226. The adhesive layer 215 and/or the protruding portion(s) 226 may help to keep the connector block 220 in a stationary position on the PCB 210. The PCB 210 may further include openings 212, 214 that are configured to receive protruding portions of the metals 240M, 250M, respectively.

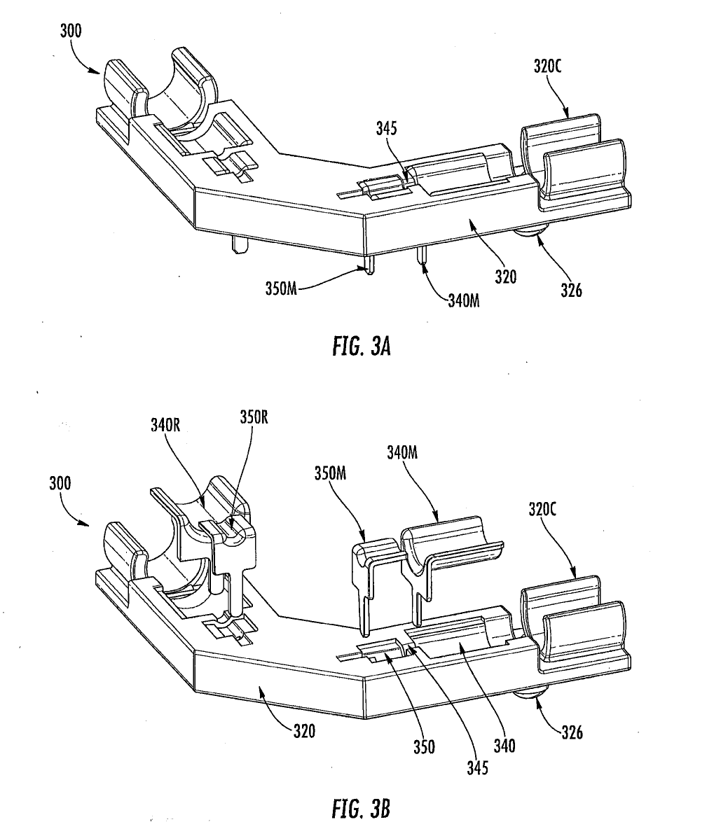

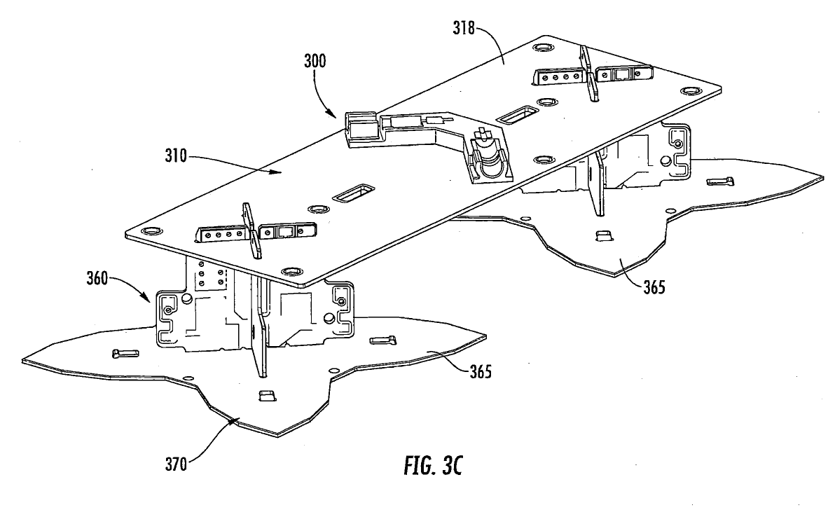

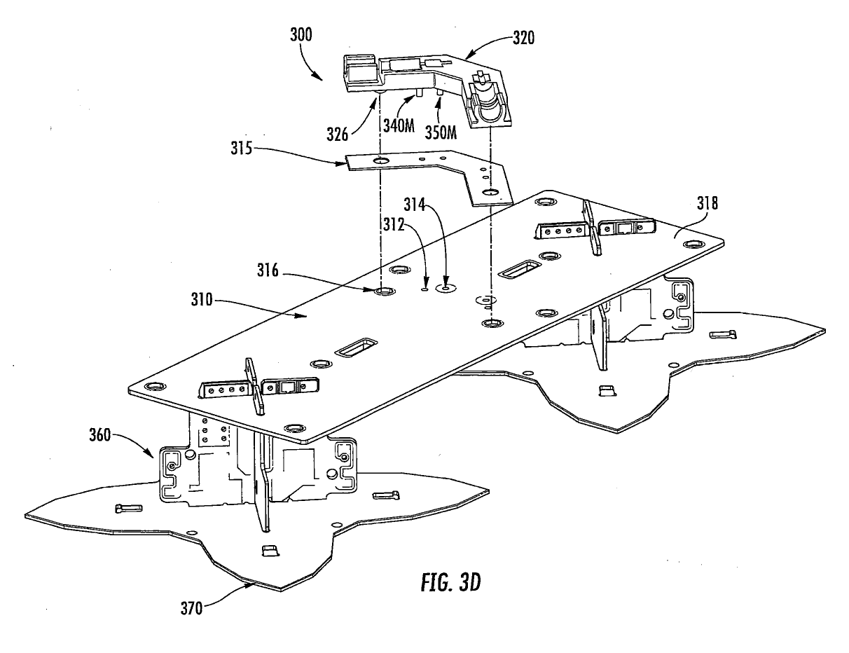

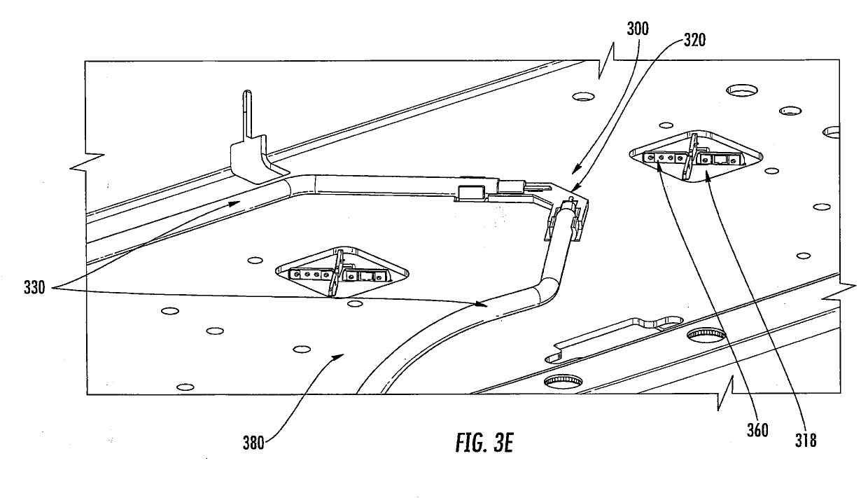

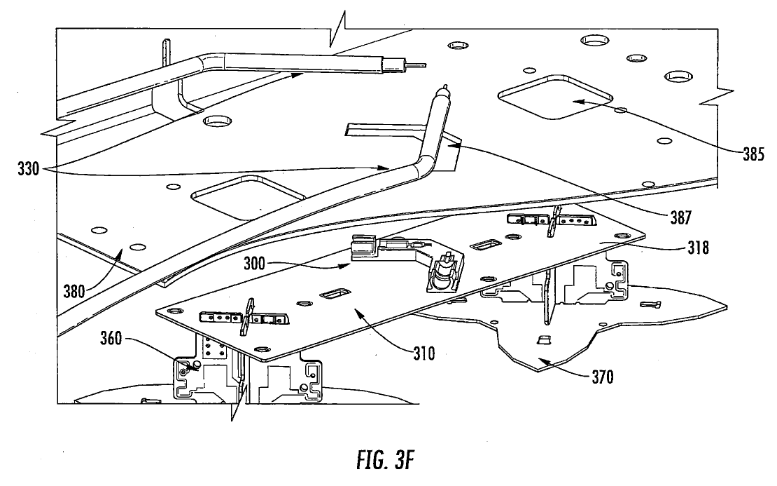

FIG. 2B also illustrates that each of the cables 230 may include three different portions: (1) a center conductor 230C, (2) a ground sleeve 230G, and (3) an insulating cover 2301. In some embodiments, the center conductor 230C may be referred to as an “inner” conductor or a “lead” conductor. Moreover, although three cables 230 are illustrated in FIGS. 2A and 2B, the connector block 220 may be configured to receive more or fewer of the cables 230. For example, the connector block 220 may be configured to receive one, two, four, five, six, seven, eight, or more of the cables 230. As an example, the PCB 210 may be a PCB of a phase shifter assembly of a base station antenna, and each of the cables 230 may connect the PCB 210 to either a radio or a feedboard assembly (e.g., the PCB 318 of feedboard assembly 310 of FIG. 3C).

In some embodiments, the terms “cable connector block assembly,” “cable connector support structure,” or “antenna cable connector support structure” may refer to an assembly or structure that includes the connector block 220 and the metals 240M, 250M, as well as one or more of the adhesive layer 215, the cables 230, and the PCB 210. For example, the cable connector block assembly 200 may be referred to as including the PCB 210. Alternatively, the words “cable connector block assembly,” “cable connector support structure,” or “antenna cable connector support structure” may refer to the connector block 220 and the metals 240M, 250M, and may be referred to as being mounted on the PCB 210.

FIG. 2C is a plan view of the cable connector block assembly 200 of FIG. 2A. The insulating cover 2301 of each of the cables 230 may be retained by a respective clip 220C. Each clip 220C may include two opposing sidewalls that protrude in a vertical direction (the z-direction in FIG. 2D) and support two portions, respectively, of the insulating cover 2301 of a respective cable 230. Accordingly, FIG. 2C, which includes three cables 230, illustrates three pairs of antenna cable retention clip sidewalls 220C. Rounded recess channels 245, 240R, 250R (FIG. 2E) that receive a cable 230 may be centered, or otherwise aligned, with respect to a pair of antenna cable retention clip sidewalls 220C. The antenna cable retention clip sidewalls 220C may be either straight or curved/bent in the z-direction. In some embodiments, a width (in the y-direction) of the antenna cable retention clip sidewalls 220C may be tapered.

FIG. 2D is a cross-sectional view taken along the line A-A′ of FIG. 2C. The line A-A′ cuts through the center conductor 230C of one of the cables 230. As illustrated by FIGS. 2C and 2D, when the insulating cover 2301 of a cable 230 is held in place by a corresponding clip 220C of the connector block 220, the ground sleeve 230G and center conductor 230C of the cable 230 contact the metals 240M and 250M, respectively. The center conductor 230C extends in an x-direction that is perpendicular to the z-direction in which the clip 220C protrudes.

FIG. 2D further illustrates the openings 212 and 214 through which the metals 240M and 250M protrude in a direction opposite the z-direction (i.e., in a negative z-direction). The metals 240M, 250M may be discrete pieces that are inserted into the connector block 220, or they could all be molded together. The openings 212 and 214 may include metal platings 212P and 214P, respectively, and thus may be metal plated through-holes. The metal platings 212P and 214P may be, for example, copper.

Moreover, a ground plane 210G may be on the PCB 210 and may be connected to the ground sleeve 230G via a portion of the metal 240M (after soldering thereof) that protrudes through the opening 212. Accordingly, both the center conductor 230C and ground 230G of the cable 230 may be soldered to the same side of the PCB 210. FIG. 2D also illustrates a protruding portion 226 of the connector block 220 that extends through an opening 216 (FIG. 2B) of the PCB 210.

FIG. 2E is a perspective view of a cable connector block assembly 200 that may be used with base station antennas according to embodiments of present inventive concepts. The cable connector block assembly 200 includes the metals 240M and 250M and the connector block 220 that are illustrated in FIG. 2A. By omitting the cables 230 and the PCB 210 of FIG. 2A, FIG. 2E provides a more detailed view of the connector block 220 and the metals 240M and 250M. Although the cables 230 and the PCB 210 are absent from this view, the structure in FIG. 2E is configured to receive and retain the cables 230, and is attachable to the PCB 210 via the adhesive layer 215 and/or the one or more protruding portions 226, as described herein with respect to FIGS. 2A-2D.

The detailed view provided by FIG. 2E illustrates that the metals 240M and 250M include recessed portions 240R and 250R, respectively. Also, the connector block 220 includes a recess 245 that extends in the x-direction between the recessed portions 240R and 250R. Although the recess 245 and the recessed portions 240R and 250R are described using the word “recess,” they may also be referred to as “curved,” “rounded,” or “non-planar” portions of the connector block 220 and the metals 240M and 250M, respectively. The shapes and sizes of the recess 245 and the recessed portions 240R and 250R correspond to the shapes and sizes of the different portions of the cable 230.

In particular, the recess 245 and the recessed portion 250R are shaped and sized to accommodate the center conductor 230C of the cable 230, whereas the recessed portion 240R is shaped and sized to receive the ground sleeve 230G of the cable 230. Accordingly, a recessed portion 250R is shallower (in the z-direction) and narrower (in the y-direction) than a corresponding recessed portion 240R that is aligned with the recessed portion 250R in the x-direction. The y-direction is perpendicular to the x-direction and the z-direction that are illustrated in FIGS. 2D and 2E. The y-direction is therefore also perpendicular to the line A-A′ that is illustrated in FIG. 2C. Furthermore, a recess 245 that is aligned with the recessed portions 240R and 250R in the x-direction may be equally shallow (in the z-direction) and narrow (in the y-direction) as the recessed portion 250R. Accordingly, one or more portions/surfaces of the metal piece 250M may be coplanar with one or more respective portions/surfaces of the recess 245.

The term “aligned,” as used with respect to the recess 245 and the recessed portions 240R and 250R, indicates that a straight line (e.g., the line A-A′ of FIG. 2C) passes through respective portions of all three of the recess 245, the recessed portion 240R, and the recessed portion 250R. For example, the recess 245 and the recessed portion 250R may be centered with respect to the recessed portion 240R. Respective outer sidewalls of the recess 245 and the metals 240M and 250M, however, are not necessarily aligned.

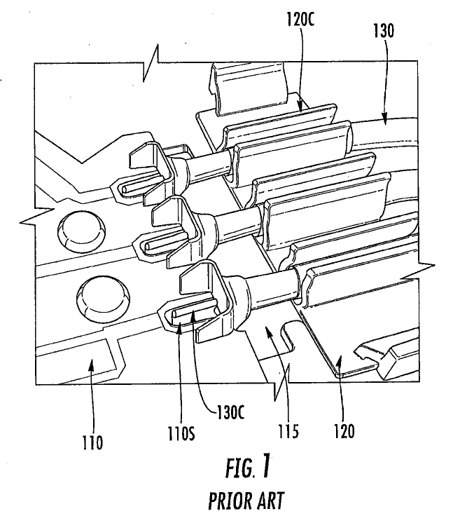

The alignment of the rounded recess channels 240R, 245, and 250R, as well as the consistent size between the channels 245 and 250R, help to keep the center lead 230C and ground sleeve 230G straight and in place. Furthermore, the absence of the gap 115 of FIG. 1 may help to increase reliability and durability. Also, because all of the cable retention clips 220C and the rounded recess channels 240R, 245, and 250R may be located on (e.g., formed on) one plane in the connector block 220, the tolerances of the cables 230 to these retention features may be significantly tighter than conventional systems in which parts are in separate planes. Moreover, whereas the conventional plastic retention structure 120 is laterally spaced apart from, and may undesirably move independently of, the PCB 110 of FIG. 1, the vast majority of the bottom surface of the connector block 220 overlaps the PCB 210, and the connector block 220 is fixed to the PCB 210.

The recessed portion 250R of the metal 250M may help provide a strong solder joint for the center conductor 230C of the cable 230. Each recessed metal piece 250M may therefore be referred to as a “center lead metal piece.” In some embodiments, the recessed metal pieces 250M may be insert molded directly into the connector block 220, and may therefore be referred to as “center lead metal insert pieces.” Similarly, the recessed metal pieces 240M, which are electrically connected to ground, may be referred as “ground metal insert pieces.” Alternatively, the recessed metals 240M and 250M could be provided by metal plating. In contrast with using the recessed metals 240M and 250M according to present inventive concepts to support the cables 230, the prior art assembly in FIG. 1 illustrates cables 130 that are soldered directly to solder areas 110S (e.g., pads) on a PCB 110. Moreover, unlike the direct soldering that is illustrated in FIG. 1, the cable connector block assembly 200 according to present inventive concepts allows the vertical positions (in the z-direction) of the center conductors 230C to be spaced apart from the PCB 210, as each center conductor 230C is elevated by the connector block 220 and does not directly contact the PCB 210.

FIG. 2F is an exploded view of the cable connector block assembly 200 of FIG. 2E. This exploded view illustrates that the metals 240M and 250M are in recesses 240 and 250, respectively, in the connector block 220. In particular, FIG. 2F illustrates three recesses 240 and three recesses 250 in the connector block 220. The connector block 220, however, may include more or fewer recesses 240 and 250. For example, the connector block 220 may include one, two, four, five, six, seven, eight, or more recesses 240 and 250. Each recess 240 is between an associated recess 250 and a pair of antenna cable retention clip sidewalls 220C.

A recess 245 extends between the recesses 240 and 250. Unlike the recesses 240 and 250, the recess 245 may be free of any metal other than the cable 230, and thus may be shallower (in the z-direction) than the recess 250, which may be shallower than the recess 240. The recesses 240 and 250 may be centered, or otherwise aligned, with respect to the pair of antenna cable retention clip sidewalls 220C. Additionally or alternatively, a front wall of the recess 240 that is in the y-z plane adjacent the recess 245 may provide a hard stop for the ground sleeve 230G of the cable 230, thus further supporting the cable 230 and holding it in place. The ground sleeve 230G has a longer radius than the center conductor 230C. In some embodiments, the center conductor 230C and the ground sleeve 230G may be referred to as “inner” and “outer” conductors, respectively, of the cable 230.

Each recess 250 may include a respective metal piece 250M. Similarly, each recess 240 may include a respective metal piece 240M. FIG. 2F thus illustrates three separate/discrete metal pieces 250M and three separate/discrete metal pieces 240M. The metal 240M of each of the recesses 240, however, will be electrically connected to ground. For example, the metal 240M of each of the recesses 240 may be electrically connected to the ground plane 210G (illustrated in FIG. 2D) after attaching the connector block 220 to the PCB 210 and soldering the metal 240M to connect to the ground plane 210G. Accordingly, in some embodiments, a single, continuous metal piece 240M may extend into each of the recesses 240, instead of using separate/discrete metal pieces 240M. The three separate/discrete metal pieces 240M that are illustrated in FIG. 2F could therefore be replaced with one combined piece 240M.

FIG. 3A is a perspective view of a cable connector block assembly 300 that may be used with base station antennas according to embodiments of present inventive concepts. The cable connector block assembly 300 includes a connector block 320, as well as metals 340M and 350M in the connector block 320. The connector block 320 includes a cable retention clip 320C and a recess 345 that is between the metal 340M and the metal 350M. The metals 340M and 350M include protruding portions that protrude from respective openings in the connector block 320 in a direction opposite the direction in which the cable retention clip 320C protrudes. The connector block 320 also includes a protruding portion 326 that protrudes in the direction in which the protruding portions of the metals 340M and 350M protrude.

In some embodiments, the connector block 320 includes a plurality of cable retention clips 320C that are configured to receive and retain a plurality of antenna RF cables, respectively. Each cable retention clip 320C may be aligned with a respective metal 340M, a respective metal 350M, and a respective recess 345. Whereas FIG. 2A illustrates a plurality of cable retention clips 220C arranged in parallel on the same end of a rectangular connector block 220, FIG. 3A illustrates two cable retention clips 320C on two opposite/different ends, respectively, of a curved connector block 320. In some embodiments, the middle portion of the curved connector block 320 that is between a first metal 350M aligned with a first cable retention clip 320C and a second metal 350M aligned with a second cable retention clip 320C may also be referred to as an “end” of the curved connector block 320, as it provides a distal/terminal region of the curved connector block 320. Respective cables that are retained by the first and second cable retention clips 320C will both point toward this end/midsection of the curved connector block 320. For example, the first and second cable retention clips 320C may be configured to receive first and second cables 330 (FIG. 3E), respectively, that extend in respective directions that intersect at an oblique angle.

The connector blocks 220 and 320 may be made of various non-metal materials. For example, each of the connector blocks 220 and 320 may be a plastic block. As an example, the plastic block may be a unitary (single piece) plastic block that includes all cable retention clips 220C (or 320C) and all recesses 240, 245, 250 (or 340, 345, 350). Each of the connector blocks 220 and 320 may thus be a molded block of an insulating material such as plastic. Accordingly, the cable retention clips 220C and 320C may be molded-in cable retention clips rather than separate pieces that are attached to the connector blocks 220 and 320. The metals 240M, 250M, 340M, and 350M may be any conductive material(s). For example, the metals 240M and 250M may be the same conductive materials or different conductive materials. Similarly, the metals 340M and 350M may be the same conductive materials or different conductive materials. The metals 340M and 350M (or the metals 240M and 250M) may be molded into the plastic of the connector block 320 (or the connector block 220) during the formation thereof so that the metals 340M and 350M (or the metals 240M and 250M) do not need to be separately attached to the plastic. Alternatively, the metals 340M and 350M (or the metals 240M and 250M) may be adhered or otherwise attached to the plastic after formation of the plastic piece.

FIG. 3B is an exploded view of the cable connector block assembly 300 of FIG. 3A. The exploded view illustrates further details of the connector block assembly 300, including the recesses 340 and 350 that are configured to receive the metals 340M and 350M, respectively. FIG. 3B also illustrates the recessed portions 340R and 350R of the metals 340M and 350M, respectively. The recessed portion 350R may be narrower and shallower than the recessed portion 340R. Moreover, the recessed portion 350R may be equally narrow and shallow as the recess 345.

FIG. 3C is a perspective view of the cable connector block assembly 300 of FIG. 3A attached to a PCB 318 of a feedboard assembly 310 of a base station antenna according to embodiments of present inventive concepts. In particular, the connector block 320 is attached to the PCB 318. The combination of the connector block 320 and its associated metals 340M, 350M and/or the PCB 318 of the feedboard assembly 310 may also be referred to as the “cable connector block assembly.” The PCB 318 may be a single printed circuit board structure that includes RF transmission lines thereon and is typically used to pass RF signals between radiating elements 370 of the feedboard assembly 310 and circuitry located behind a ground plane structure of the base station antenna. In some embodiments, a pair of PCBs 360, which may also be referred to as a “feed stalk,” may be attached to the PCB 318. For example, a portion of each PCB 360 may protrude through an opening in the PCB 318. The PCBs 360 are connected to dipole radiators 365. Each pair of PCBs 360 and dipole radiators 365 form a radiating element 370 of the base station antenna. The combination of the PCB 318 and its associated radiating elements 370 may be referred to as the feedboard assembly 310.

FIG. 3C illustrates an example in which two radiating elements 370 of the base station antenna are connected to the PCB 318. Each radiating element 370 may be connected to two cables 330 (FIG. 3E; one for each polarization) that a connector block 320 is configured to receive and retain. Accordingly, although FIGS. 3C-3E illustrate one connector block assembly 300 having one connector block 320, two connector block assemblies 300 having respective connector blocks 320 may be provided to accommodate the two radiating elements 370. A feedboard assembly 310, however, may support more or fewer cables 330 or connector blocks 320. For example, the feedboard assembly 310 may support one, three, four, or more cables 330.

FIG. 3D is an exploded view of the cable connector block assembly 300 and feedboard assembly 310 of FIG. 3C. This exploded view illustrates that the connector block 320 of the cable connector block assembly 300 includes protruding portions 326. Moreover, the PCB 318 of the feedboard assembly 310 includes openings 316 that are configured to receive the respective protruding portions 326. Accordingly, the connector block 320 may be attached to the PCB 318 of the feedboard assembly 310 by using one or more protruding portions 326. Additionally or alternatively, the connector block 320 may be attached to the PCB 318 by an adhesive layer 315, or via other attachment means.

The PCB 318 of the feedboard assembly 310 also includes openings 312 and 314 through which portions of the metal 340M and the metal 350M, respectively, may protrude. After placing the protruding portions of the metal 340M and the metal 350M through the respective openings 312 and 314, these protruding portions may be soldered to the PCB 318 of the feedboard assembly 310.

FIG. 3E is a perspective view of an antenna reflector 380 on the feedboard assembly 310 of FIG. 3C according to embodiments of present inventive concepts. The antenna reflector 380 reflects RF energy. For example, the antenna reflector 380 may reflect electromagnetic waves emanating from the radiating element(s) 370. FIG. 3E also illustrates two antenna RF cables 330 that are retained by the cable connector block assembly 300. In some embodiments, the cables 330 may have the same structure as the cables 230 of FIG. 2B. Furthermore, FIG. 3E illustrates portions of PCBs 360 that protrude through openings in the PCB 318 of the feedboard assembly 310.

FIG. 3F is an exploded view of the antenna reflector 380 and feedboard assembly 310 of FIG. 3E. This exploded view illustrates openings 385 and 387 of the antenna reflector 380 that fit over/around the protruding portion of the PCB 360 and the connector block 320, respectively. The cable retention clip(s) 320C of the connector block 320 may protrude through the opening 387.

Referring back to FIG. 2D, the center conductor 230C of each cable 230 may be soldered to a respective metal piece 250M, and the portion of the metal piece 250M that protrudes through the opening 214 may be soldered to the metal plating 214P of the PCB 210. Similarly, referring to FIGS. 3A-3F, a center conductor of each cable 330 may be soldered to a respective metal piece 350M, and the portion of the metal piece 350M that protrudes through the opening 314 may be soldered to a pad on the PCB 318 of the feedboard assembly 310. The pad may connect to, or be a part of, an RF transmission line on the PCB 318 that connects to one of the feed stalk PCBs 360.

In contrast with direct soldering of the cables 130 to the PCB 110 in FIG. 1, various embodiments described herein provide a cable connector block assembly 200 (or 300) with rounded recess channels 240R, 245, 250R (or 340R, 345, 350R) that help to strengthen solder joints. In particular, the rounded recess channels 240R, 245, 250R (or 340R, 345, 350R) are in a connector block 220 (or 320) that is mounted to an RF communications board (a PCB 210 or a PCB 318) before soldering metal 240M, 250M (or 340M, 350M) of the cable connector block assembly 200 (or 300) to the PCB 210 or the PCB 318.

The connector block 220 (or 320) further includes built-in cable retention clips 220C (or 320C). A single connector block 220 (or 320) thus includes a combination of the cable retention clips 220C (or 320C) and the rounded recess channels 240R, 245, 250R (or 340R, 345, 350R). The locations of the cable retention clips 220C (or 320C) and the rounded recess channels 240R, 245, 250R (or 340R, 345, 350R) can therefore be well defined and finely controlled, which may improve retention of, and inhibit bending of, the cables 230 (or 330). The plastic retention structure 120 of FIG. 1, on the other hand, provides limited support to the cables 130, and thus may result in undesirable bending and process variation.

Providing the cable connector block assembly 200 (or 300) may therefore provide a number of advantages. These advantages include simplifying and strengthening antenna RF cable 230 (or 330) connections. For example, the connections may be improved due to improved solderability provided by the recessed metal pieces 240M, 250M (or 340M, 350M) in the connector block 220 (or 320). Moreover, the same connector block 220 (or 320) supports all three portions 230C, 230G, 2301 (or 330C, 330G, 3301) of the cables 230 (or 330), and thereby both simplifies and strengthens support. Accordingly, the cable connector block assembly 200 (or 300) may help restrict undesired movement of the cables 230 (or 330), and may strengthen electrical connections with the cables 230 (or 330), thereby improving performance of the associated base station antenna.

Present inventive concepts have been described above with reference to the accompanying drawings. Present inventive concepts are not limited to the illustrated embodiments. Rather, these embodiments are intended to fully and completely disclose present inventive concepts to those skilled in this art. In the drawings, like numbers refer to like elements throughout. Thicknesses and dimensions of some components may be exaggerated for clarity.

Spatially relative terms, such as “under,” “below,” “lower,” “over,” “upper,” “top,” “bottom,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the example term “under” can encompass both an orientation of over and under. The device may be otherwise oriented (rotated 90 degrees or at other orientations) and the spatially relative descriptors used herein interpreted accordingly.

Herein, the terms “attached,” “connected,” “interconnected,” “contacting,” “mounted,” and the like can mean either direct or indirect attachment or contact between elements, unless stated otherwise.

Well-known functions or constructions may not be described in detail for brevity and/or clarity. As used herein the expression “and/or” includes any and all combinations of one or more of the associated listed items.

The terminology used herein is for the purpose of describing particular embodiments only and is not intended to be limiting of present inventive concepts. As used herein, the singular forms “a,” “an,” and “the” are intended to include the plural forms as well, unless the context clearly indicates otherwise. It will be further understood that the terms “comprises,” “comprising,” “includes,” and/or “including” when used in this specification, specify the presence of stated features, operations, elements, and/or components, but do not preclude the presence or addition of one or more other features, operations, elements, components, and/or groups thereof.

That which is claimed is:

1. A cable connector support structure comprising:
a connector block comprising:
a plurality of cable retention clips on a first end of the connector block;
a first plurality of recesses adjacent the plurality of cable retention clips; and
a second plurality of recesses on a second end of the connector block that is opposite the first end;
metal in the first plurality of recesses; and
a plurality of metal pieces in the second plurality of recesses, respectively,
wherein the plurality of metal pieces comprises respective recessed portions that are shallower and narrower than respective recessed portions of the metal in the first plurality of recesses.

2. The cable connector support structure of claim 1, further comprising a base station antenna Printed Circuit Board (PCB) comprising openings through which the metal and the plurality of metal pieces protrude.

3. The cable connector support structure of claim 1,
wherein the metal comprises a first plurality of metal pieces in the first plurality of recesses, respectively, and
wherein the plurality of metal pieces in the second plurality of recesses comprises a second plurality of metal pieces.

4. The cable connector support structure of claim 1, wherein the metal comprises a single, continuous metal piece that is in each of the first plurality of recesses.

5. An antenna cable connector support structure comprising:
a connector block comprising:
a pair of antenna cable retention clip sidewalls on a first portion of the connector block;
a first recess on a second portion of the connector block; and
a second recess between the first recess and the pair of antenna cable retention clip sidewalls; and
first and second metal pieces in the first and second recesses, respectively.

6. The antenna cable connector support structure of claim 5,
wherein the first and second portions of the connector block comprise first and second ends, respectively, of the connector block, and
wherein the antenna cable connector support structure further comprises a base station antenna Printed Circuit Board (PCB) comprising first and second openings through which the first and second metal pieces, respectively, protrude.

7. The antenna cable connector support structure of claim 5, wherein the first and second recesses are aligned with respect to the pair of antenna cable retention clip sidewalls.

8. The antenna cable connector support structure of claim 5, further comprising a third recess that extends between the first and second recesses,
wherein the third recess is shallower than the first recess, and
wherein the first recess is shallower than the second recess.

9. The antenna cable connector support structure of claim 8,
wherein the first metal piece comprises a recessed portion that is shallower and narrower than a recessed portion of the second metal piece, and
wherein the third recess is equally shallow and narrow as the recessed portion of the first metal piece.

10. The antenna cable connector support structure of claim 8, wherein a portion of the first metal piece is coplanar with a portion of the third recess.

11. The antenna cable connector support structure of claim 5,
wherein the pair of antenna cable retention clip sidewalls protrudes from the connector block in a first direction, and
wherein the first and second metal pieces comprise respective protruding portions that protrude from the connector block in a second direction that is opposite the first direction.

12. The antenna cable connector support structure of claim 5, further comprising a base station antenna feedboard assembly having a Printed Circuit Board (PCB) with first and second openings through which the first and second metal pieces, respectively, protrude.

13. A cable connector block assembly comprising:
a plastic block comprising: a cable retention clip, a first metal piece, and a second metal piece configured to receive different first, second, and third portions, respectively, of a cable;
a Printed Circuit Board (PCB) comprising first and second openings through which the first and second metal pieces, respectively, protrude.

14. The cable connector block assembly of claim 13, further comprising an adhesive material connecting the plastic block and the PCB.

15. The cable connector block assembly of claim 13, wherein the first metal piece comprises a recessed portion that is shallower and narrower than a recessed portion of the second metal piece.

16. The cable connector block assembly of claim 13, wherein the cable retention clip, the first metal piece, and the second metal piece of the plastic block are configured to receive different first, second, and third portions, respectively, of a base station antenna cable.

17. The cable connector block assembly of claim 16, wherein the PCB comprises a phase shifter assembly PCB of a base station antenna.

18. The cable connector block assembly of claim 13, wherein the PCB comprises a PCB of a feedboard assembly of a base station antenna.

19. The cable connector block assembly of claim 18, further comprising an antenna reflector on the feedboard assembly, the antenna reflector comprising an opening through which the cable retention clip of the plastic block protrudes.

20. The cable connector block assembly of claim 18,
wherein the PCB of the feedboard assembly comprises first and second openings through which first and second feed stalk Printed Circuit Boards (PCBs) protrude, and
wherein the first and second PCBs are connected to a radiating element of the base station antenna.

21. The cable connector block assembly of claim 13,
wherein the cable retention clip comprises a first cable retention clip configured to receive a first cable that extends in a first direction, and
wherein the plastic block further comprises a second cable retention clip configured to receive a second cable that extends in a second direction that intersects the first direction at an oblique angle.

22. The cable connector block assembly of claim 13,
wherein the cable retention clip protrudes in a first direction,
wherein the plastic block further comprises a protruding portion that protrudes in a second direction that is opposite the first direction, and
wherein the PCB further comprises a third opening configured to receive the protruding portion of the plastic block.
